(19) United States
(12) Patent Application Publication
(10) Pub. No.: US 2005/0199872 A1
(43) Pub. Date: Sep. 15, 2005

(54) Silicon-germanium thin layer semiconductor structure with variable silicon-germanium composition and method of fabrication

(75) Inventors: Pradip K. Roy, Orlando, FL (US); Anthony Dip, Cedar Creek, TX (US); Allen J. Leith, Austin, TX (US); Seungho Oh, Austin, TX (US)

Correspondence Address: WOOD, HERRON & EVANS, LLP, 2700 CAREW TOWER, 441 VINE STREET, CINCINNATI, OH, 45202, US

(73) Assignee: Tokyo Electron Limited of TBS Broadcast Center, Tokyo (JP)

(21) Appl. No.: 10/797,425

(22) Filed: Mar. 10, 2004

(51) Int. Cl. H01L 29/06

(52) U.S. Cl. 257/19

(57) ABSTRACT

A SiGe thin layer semiconductor structure containing a substrate having a dielectric layer, a variable composition SiₓGe₁₋ₓ layer on dielectric layer, and a Si cap layer on the variable composition SiₓGe₁₋ₓ layer. The variable composition SiₓGe₁₋ₓ layer can contain a SiₓGe₁₋ₓ layer with a graded Ge content or a plurality of SiₓGe₁₋ₓ sub-layers each with different Ge content. In one embodiment of the invention, the SiGe thin layer semiconductor structure contains a semiconductor substrate having a dielectric layer, a Si-containing seed layer on the dielectric layer, a variable composition SiₓGe₁₋ₓ layer on the seed layer, and a Si cap layer on the variable composition SiₓGe₁₋ₓ layer. A method and processing tool for fabricating the SiGe thin layer semiconductor structure are also provided.

### FIELD OF THE INVENTION

The present invention relates to semiconductor structures and semiconductor processing, and more particularly, to a SiGe thin layer semiconductor structure with variable SiGe composition and method of fabrication.

### BACKGROUND OF THE INVENTION

The addition of germanium (Ge) to silicon (Si) technologies to form SiGe devices has created a revolution in the semiconductor industry. The Ge is added to form high-performance heterojunction bipolar transistors (HBT) that can operate at speeds much higher than standard silicon bipolar transistors. The SiGe devices can also be integrated into standard complimentary metal oxide semiconductor (CMOS) logic technologies, resulting in the integration of high performance analog and RF circuits with dense CMOS logic. Polycrystalline silicon-germanium (poly-SiGe) is a promising alternative to polycrystalline Si (poly-Si) as the gate electrode material for future scaling of CMOS devices, because it can provide an added degree of threshold-voltage control, as well as suppression of the gate-depletion effect for devices with thin gate oxides.

In a conventional CMOS fabrication process, the sheet resistance of the narrow gate lines is reduced to acceptable levels by the self-aligned formation of silicide (“salicide”) in the upper portion of the gate film, where amorphous Si or poly-Si react with a metal (e.g., Co or Ni) to form a new compound self-aligned to the desired device component structure, such as the gate, source, and drain regions. However, the silicidation reaction of poly-SiGe differs drastically from that of poly-Si. Ge atoms from the poly-SiGe layer can segregate at grain boundaries and thus form high resistance layers during the silicidation reaction.

### SUMMARY OF THE INVENTION

The present invention provides a SiGe thin layer semiconductor structure that reduces or solves the above described and/or other problems with prior art semiconductor devices. The present invention further provides a thin layer SiGe semiconductor structure that reduces the poly depletion effect without compromising salicide integrity. To this end, a SiGe thin layer semiconductor structure is provided containing a substrate having a dielectric layer, a variable composition SiₓGe₁₋ₓ layer on the dielectric layer, and a Si cap layer on the variable composition SiₓGe₁₋ₓ layer. The variable composition SiₓGe₁₋ₓ layer can contain a SiₓGe₁₋ₓ layer with a graded Ge content or a plurality of SiₓGe₁₋ₓ sub-layers each with different Ge content.

In one embodiment of the invention, the SiGe thin layer semiconductor structure further contains a Si-containing seed layer on the dielectric layer, with the variable composition SiₓGe₁₋ₓ layer being formed on the seed layer.

Also provided are a method and a processing tool for forming a SiGe thin layer semiconductor device.

### BRIEF DESCRIPTION OF THE DRAWINGS

In the accompanying drawings:

FIG. 1A shows a simplified block diagram of a batch-type processing system for forming a Si-containing layer on a substrate according to an embodiment of the invention;

FIG. 1B shows a simplified block diagram of another batch-type processing system for forming a Si-containing layer on a substrate according to an embodiment of the invention;

FIG. 2 shows a simplified block diagram of a processing tool according to an embodiment of the invention;

FIG. 3 shows a flow diagram for forming a SiGe thin layer semiconductor structure containing a variable composition SiₓGe₁₋ₓ layer according to an embodiment of the invention;

FIG. 4 schematically shows a SiGe thin layer semiconductor structure containing a variable composition SiₓGe₁₋ₓ layer and Ge content profile of the structure according to an embodiment of the invention;

FIG. 5 schematically shows a SiGe thin layer semiconductor structure containing a variable composition SiₓGe₁₋ₓ layer and Ge content profile of the structure according to another embodiment of the invention;

FIG. 5A schematically shows another embodiment of a SiGe thin layer semiconductor structure containing a Si-containing seed layer and a variable composition SiₓGe₁₋ₓ layer; and

FIG. 6 shows a general-purpose computer that may be used to implement the present invention.

### DETAILED DESCRIPTION OF THE INVENTION

As noted in the Background of the Invention section above, the use of traditional SiGe layers in gate electrode structures suffers from segregation of Ge atoms at grain boundaries and formation of high resistance layers during a silicidation reaction. Common SiGe gate electrode structures contain a seed layer of either amorphous Si or poly-Si deposited on a substrate, a SiGe gate electrode layer deposited on the seed layer, and a poly-Si (or amorphous Si) cap layer deposited on the SiGe gate electrode layer.

A poly-Si or amorphous Si cap layer that is consumed during the silicide process can be formed on a SiGe gate electrode. A Si cap is used because direct silicidation of SiGe alloy usually results in poor performance due to the formation of a higher resistivity material. However, a sharp Ge concentration at the SiGe/cap interface and strain field gradients in the gate electrode structure cause Ge to outdiffuse from the SiGe layer to the surface of the gate electrode, which destroys salicide integrity. One method to reduce the problem is to reduce Ge content in the SiGe layer below about 0.1. However, such a reduction in Ge content results in loss of the gains obtained in lowering the poly-depletion effects by adding Ge to the structure.

The current invention reduces these problems by using a SiGe thin layer semiconductor structure containing a variable composition SiGe structure that maintains the benefit of reducing the poly-depletion effect without compromising salicide integrity. In the invention, a SiGe layer composition is denoted by SiₓGe₁₋ₓ, where x is the atomic fraction of Si (Si content) in the SiₓGe₁₋ₓ layer, and 1-x is the atomic fraction of Ge in the SiₓGe₁₋ₓ layer (Ge content), respectively.

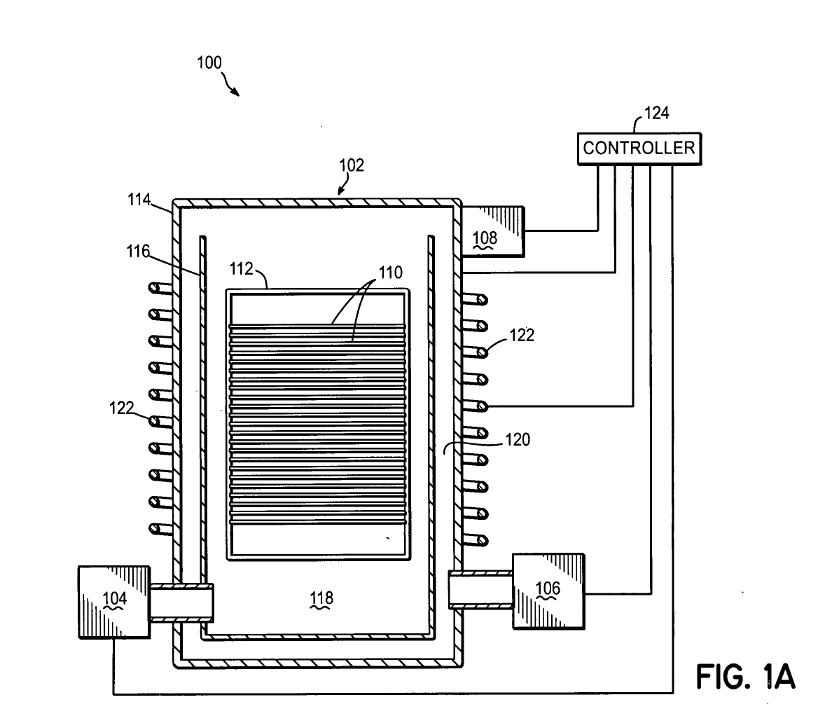

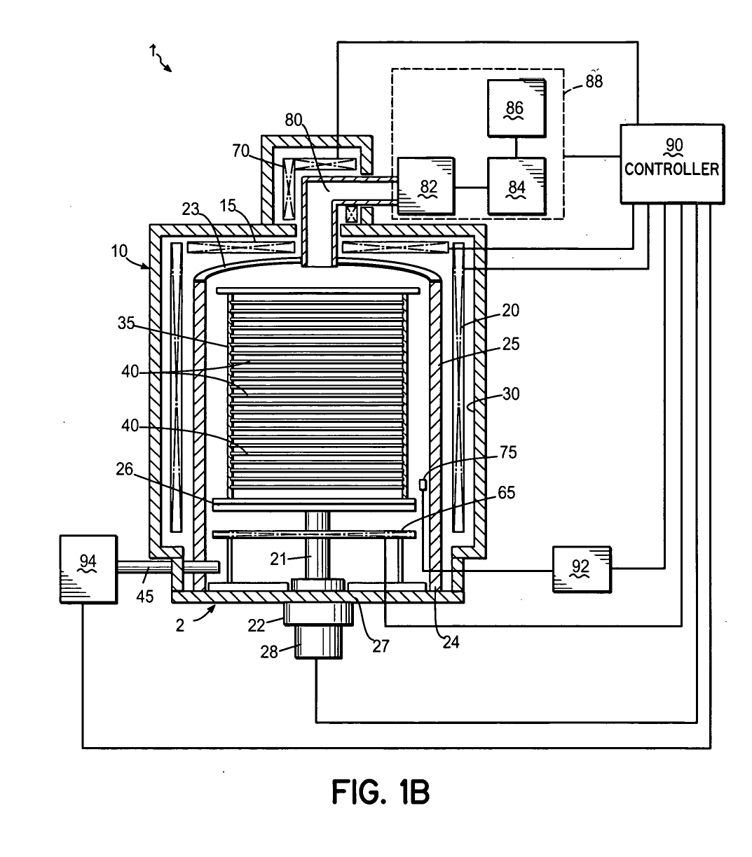

Referring now to the drawings, FIG. 1A shows a simplified block diagram of a batch-type processing system for forming a Si-containing layer on a substrate according to an embodiment of the invention. The batch-type processing system 100 includes a process chamber 102, a gas injection system 104, a heater 122, a vacuum pumping system 106, a process monitoring system 108, and a controller 124. Multiple substrates 110 can be loaded into the process chamber 102 and processed using substrate holder 112. Furthermore, the process chamber 102 comprises an outer section 114 and an inner section 116. In one embodiment of the invention, the inner section 116 can be a process tube.

The gas injection system 104 can introduce gases into the process chamber 102 for purging the process chamber 102, and for preparing, cleaning, and processing the substrates 110. The gas injection system 104 can, for example, include a liquid delivery system (LDS) (not shown) that contains a vaporizer to vaporize a Si-containing liquid, e.g., hexachlorodisilane (Si₂Cl₆). The vaporized liquid can be flowed into the process chamber 102 with or without the aid of a carrier gas. For example, when a carrier gas is used, the gas injection system can include a bubbling system where the carrier gas is bubbled through a reservoir containing the Si-containing liquid. In addition, the gas injection system 104 can be configured for flowing a gaseous Si-containing gas, e.g., silane (SiH₄), from a high-pressure container. Furthermore, the above-mentioned gas flows can, for example, contain an inert gas and a hydrogen-containing gas. The hydrogen-containing gas can, for example, contain H₂. A plurality of gas supply lines can be arranged to flow gases into the process chamber 102. The gases can be introduced into volume 118, defined by the inner section 116, and exposed to substrates 110. Thereafter, the gases can flow into the volume 120, defined by the inner section 116 and the outer section 114, and exhausted from the process chamber 102 by the vacuum pumping system 106.

Substrates 110 can be loaded into the process chamber 102 and processed using substrate holder 112. The batch-type processing system 100 can allow for a large number of tightly stacked substrates 110 to be processed, thereby resulting in high substrate throughput. A substrate batch size can, for example, be about 100 substrates (wafers), or less. Alternately, the batch size can be about 25 substrates, or less. The process chamber 102 can, for example, process a substrate of any size, for example 200 mm substrates, 300 mm substrates, or even larger substrates. The substrates 110 can, for example, comprise semiconductor substrates (e.g. silicon or compound semiconductor), LCD substrates, and glass substrates. In addition to clean substrates, substrates with dielectric layers formed thereon can be utilized, including but not limited to, oxide layers, nitride layers, and oxynitride layers.

The batch-type processing system 100 can be controlled by a controller 124 capable of generating control voltages sufficient to communicate and activate inputs of the batch-type processing system 100 as well as monitor outputs from the batch-type processing system 100. Moreover, the controller 124 can be coupled to and exchange information with process chamber 102, gas injection system 104, heater 122, process monitoring system 108, and vacuum pumping system 106. For example, a program stored in the memory of the controller 124 can be utilized to control the aforementioned components of the batch-type processing system 100 according to a stored process recipe. One example of controller 124 is a DELL PRECISION WORKSTATION 610™, available from Dell Corporation, Dallas, Tex.

Real-time process monitoring can be carried out using process-monitoring system 108. In general, the process monitoring system 108 is a versatile monitoring system and can, for example, comprise a mass spectrometer (MS) or a Fourier Transform Infra-red (FTIR) spectrometer. The process monitoring system 108 can provide qualitative and quantitative analysis of the gaseous chemical species in the process environment. Process parameters that can be monitored include gas flows, gas pressure, ratios of gaseous species, and gas purities. These parameters can be correlated with prior process results and various physical properties of the deposited Si-containing film.

FIG. 1B shows a simplified block diagram of another batch-type processing system for forming a Si-containing film on a substrate according to an embodiment of the invention. The batch-type processing system 1 contains a process chamber 10 and a process tube 25 that has a upper end connected to a exhaust pipe 80, and a lower end hermetically joined to a lid 27 of cylindrical manifold 2. The exhaust pipe 80 discharges gases from the process tube 25 to a vacuum pumping system 88 to maintain a pre-determined atmospheric or below atmospheric pressure in the processing system 1. A substrate holder 35 for holding a plurality of substrates (wafers) 40 in a tier-like manner (in respective horizontal planes at vertical intervals) is placed in the process tube 25. The substrate holder 35 resides on a turntable 26 that is mounted on a rotating shaft 21 penetrating the lid 27 and driven by a motor 28. The turntable 26 can be rotated during processing to improve overall film uniformity or, alternately, the turntable can be stationary during processing. The lid 27 is mounted on an elevator 22 for transferring the substrate holder 35 in and out of the reaction tube 25. When the lid 27 is positioned at its uppermost position, the lid 27 is adapted to close the open end of the manifold 2.

A plurality of gas supply lines can be arranged around the manifold 2 to supply a plurality of gases into the process tube 25 through the gas supply lines. In FIG. 1B, only one gas supply line 45 among the plurality of gas supply lines is shown. The gas supply line 45 is connected to a gas injection system 94. A cylindrical heat reflector 30 is disposed so as to cover the reaction tube 25. The heat reflector 30 has a mirror-finished inner surface to suppress dissipation of radiation heat radiated by main heater 20, bottom heater 65, top heater 15, and exhaust pipe heater 70. A helical cooling water passage (not shown) is formed in the wall of the process chamber 10 as a cooling medium passage.

A vacuum pumping system 88 comprises a vacuum pump 86, a trap 84, and automatic pressure controller (APC) 82. The vacuum pump 86 can, for example, include a dry vacuum pump capable of a pumping speed up to 20,000 liters per second (and greater). During processing, gases can be introduced into the process chamber 10 via the gas injection system 94 and the process pressure can be adjusted by the APC 82. The trap 84 can collect unreacted precursor material and by-products from the process chamber 10.

The process monitoring system 92 comprises a sensor 75 capable of real-time process monitoring and can, for example, comprise a MS or a FTIR spectrometer. A controller 90 includes a microprocessor, a memory, and a digital I/O port capable of generating control voltages sufficient to communicate and activate inputs to the processing system 1 as well as monitor outputs from the processing system 1. Moreover, the controller 90 is coupled to and can exchange information with gas injection system 94, motor 28, process monitoring system 92, heaters 20, 15, 65, and 70, and vacuum pumping system 88. As with the controller 124 of FIG. 1A, the controller 90 may be implemented as a DELL PRECISION WORKSTATION 610™.

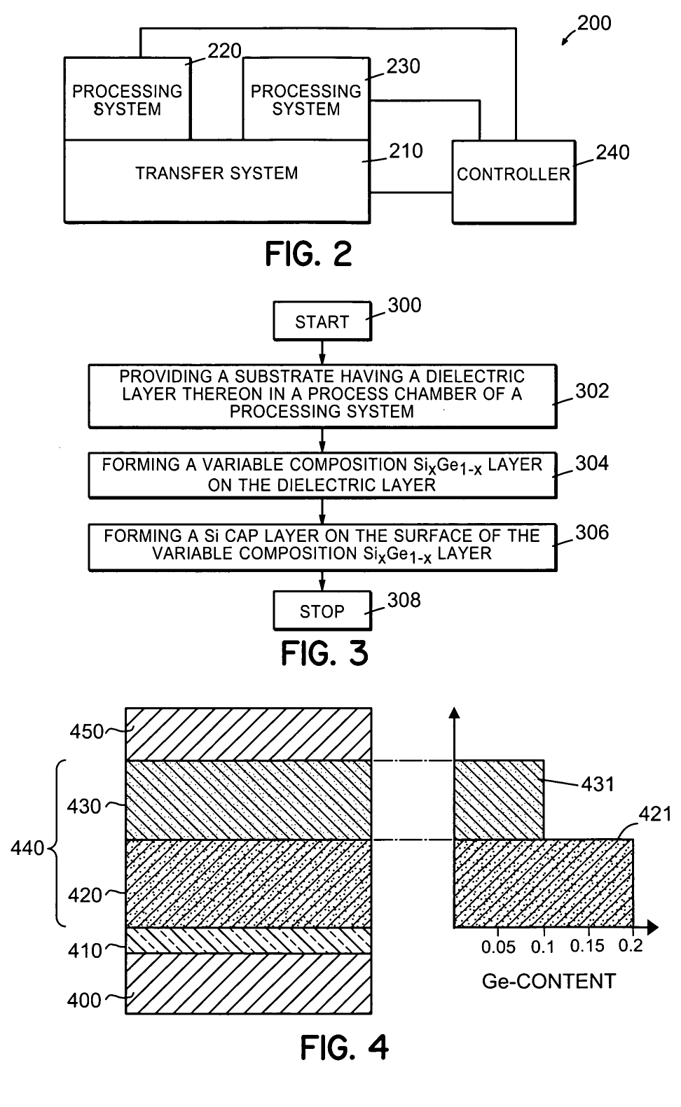

FIG. 2 shows a simplified block diagram of a processing tool according to an embodiment of the invention. The processing tool 200 comprises processing systems 220 and 230, a (robotic) transfer system 210 configured for transferring substrates within the processing tool 200, and a controller 240 configured to control the components of the processing tool 200. In another embodiment of the invention, the processing tool 200 can comprise a single processing system or, alternately, can comprise more than two processing systems. In FIG. 2, the processing systems 220 and 230 can, for example, perform at least one of the following processes: (a) form a Si-containing layer on a substrate, and (b) form a variable composition SiₓGe₁₋ₓ layer on a substrate. In (a), the Si-containing layer can be a Si-containing seed layer or a Si cap layer. In one embodiment of the invention, the processes (a) and (b) can be performed in different processing systems. In another embodiment of the invention, both (a) and (b) can be carried out in the same processing system. In one embodiment of the invention, at least one of the processing systems can include a batch-type processing system or a single wafer processing system. In another embodiment of the invention, at least one of the processing systems can include a thermal processing system, a plasma processing system, or an atomic layer deposition system.

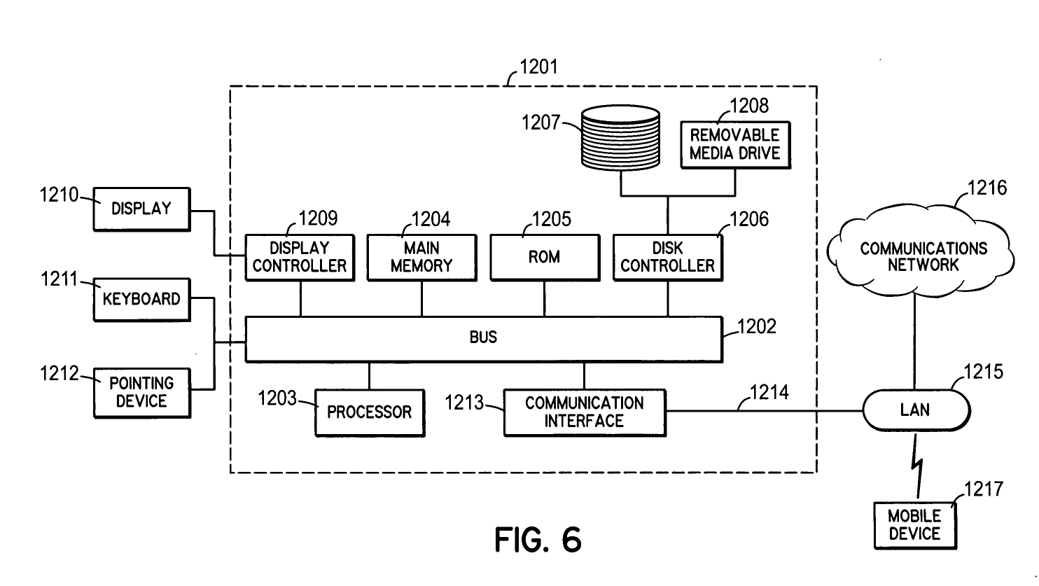

As with the controllers in FIGS. 1A and 1B, the controller 240 may be implemented as a DELL PRECISION WORKSTATION 610™. Moreover, the controller of any of FIGS. 1A-1B and 2 may be implemented as a general-purpose computer system such as that described below with respect to FIG. 6.

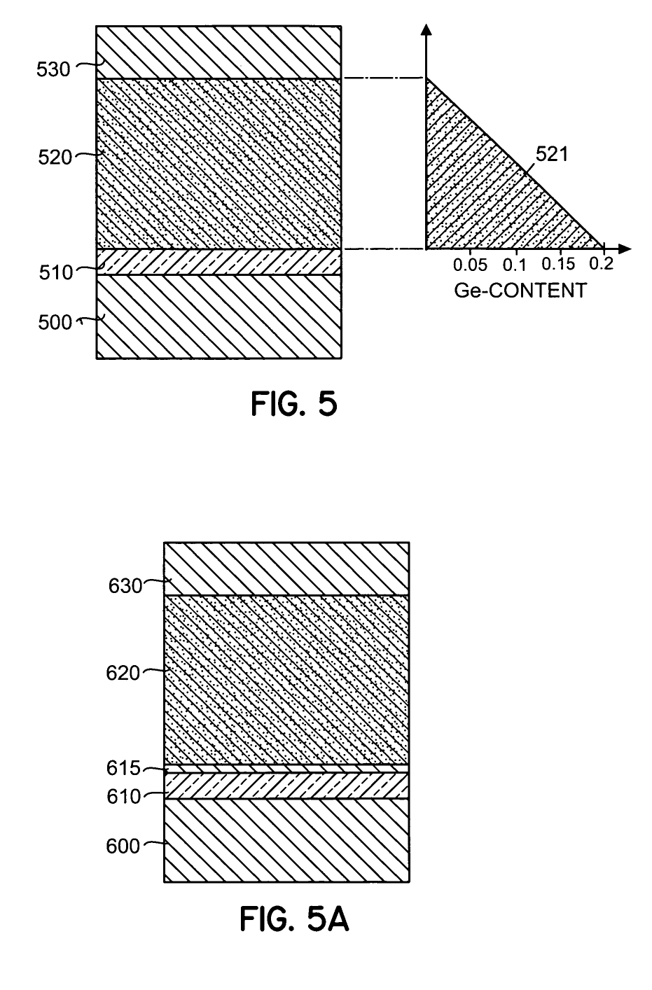

Referring now to FIGS. 3 and 4 to illustrate embodiments of the invention, FIG. 3 shows a flow diagram for forming a SiGe thin layer semiconductor structure containing a variable composition SiₓGe₁₋ₓ layer according to an embodiment of the invention, and FIG. 4 schematically shows a SiGe thin layer semiconductor structure containing a variable composition SiₓGe₁₋ₓ layer and Ge content profile of the structure according to an embodiment of the invention. At 300, the process of the present invention is started. At 302, a substrate 400 containing a dielectric layer 410 is provided in a process chamber of a processing system. The substrate 400 can be of any size, for example a 200 mm substrate, a 300 mm substrate, or an even larger substrate. The dielectric layer 410 can, for example, be an oxide layer (e.g., SiO₂), a nitride layer (e.g., SiN), an oxynitride layer (e.g., SiOₓN_{y}), or a high-k layer (e.g., HfO₂ or HfSiₓO_{y}), wherein “k” refers to the dielectric constant of the material. The processing system may be the batch-type processing system 100 or 1 described in FIG. 1A or 1B, respectively, and may be provided as a part of a processing tool 200 such as described in FIG. 2. Alternatively, the processing system may be a single wafer processing system.

At 304, a variable composition SiₓGe₁₋ₓ layer 440 is formed on the dielectric layer 410. In the embodiment shown in FIG. 4, the variable composition SiₓGe₁₋ₓ layer 440 contains a first SiₓGe₁₋ₓ sublayer 420, with a Ge content 421 of about 0.2, formed on the dielectric layer 410, and a second SiₓGe₁₋ₓ sublayer 430, with a Ge content 431 of about 0.1, formed on the first SiₓGe₁₋ₓ sublayer 420. Alternately, the Ge content 421 can be less than 0.2 and the Ge content 431 can be less than 0.1. In another embodiment of the invention, the first SiₓGe₁₋ₓ sublayer 420, can have a Ge content of between about 0.3 and about 0.5, and the second SiₓGe₁₋ₓ sublayer 440, can have a Ge content between about 0.05 and about 0.15. As will be appreciated by one skilled in the art, the invention is not limited to the above-mentioned SiₓGe₁₋ₓ sublayer compositions, as a large range of SiₓGe₁₋ₓ sublayer compositions can be used. Furthermore, the invention is not limited by a variable composition SiₓGe₁₋ₓ layer 440 containing two SiₓGe₁₋ₓ sublayers 430 and 420, as any number of sublayers may be used. It may be appreciated that one or more first SiₓGe₁₋ₓ sublayers 420 adjacent the dielectric layer 410 have a higher Ge content, for example about 0.2 to about 0.5, to achieve a reduction in the poly-depletion effects, while one or more second SiₓGe₁₋ₓ sublayers 430 have a lower Ge content, for example about 0.1 or less, to ensure salicide integrity. In one embodiment of the invention, the first SiₓGe₁₋ₓ sublayer 420 and the second SiₓGe₁₋ₓ sublayer 430 can be between about 300 Å and about 500 Å thick each. The SiₓGe₁₋ₓ sublayers 430 and 420 can be formed by a chemical vapor deposition (CVD) process using a Si-containing gas, for example silane (SiH₄), disilane (Si₂H₆), dichlorosilane (SiH₂Cl₂), or hexachlorodisilane (Si₂Cl₆), and a Ge-containing gas that can, for example, be selected from GeH₄ and GeCl₄.

Still referring to FIGS. 3 and 4, at 306, a Si cap layer 450 is formed on the variable composition SiₓGe₁₋ₓ layer 440. The Si cap layer 450 can be an amorphous Si layer or a poly-Si layer. The thickness of the Si cap layer 450 can, for example, be between about 300 Å and about 500 Å. The Si cap layer 450 can, for example, be formed in a CVD process using at least one of SiH₄, Si₂H₆, SiH₂Cl₂, and Si₂Cl₆. At 308, the process ends.

In another embodiment of the invention, as schematically shown in FIG. 5, a variable composition SiₓGe₁₋ₓ layer 520 can have a continuously variable (graded) SiₓGe₁₋ₓ composition. The structure in FIG. 5 further contains a substrate 500, a dielectric layer 510, and a Si cap layer 530. The thickness of the variable composition SiₓGe₁₋ₓ layer 520 formed on dielectric layer 510 can, for example, be between about 600 Å and about 1000 Å. The Ge content 521 in continuously variable SiₓGe₁₋ₓ layer 520 can be varied from high, e.g., a Ge content of about 0.2, at the interface of layers 510 and 520, to low, e.g., a Ge content approaching zero, at the interface of layers 520 and 530. In another embodiment of the invention, the Ge content at the interface of layers 510 and 520 can be greater than 0.2, for example between about 0.5 and about 0.3. This graded Ge content also achieves a reduction in poly-depletion effects by addition of high Ge content near the interface with dielectric layer 510 and ensures salicide integrity by providing little to no Ge content near the interface with the Si cap layer 530. The continuously variable composition SiₓGe₁₋ₓ layer 520 can, for example, be formed by varying the flow of the Ge-containing gas and/or the Si-containing gas during formation of the SiₓGe₁₋ₓ, layer 520. In yet another embodiment of the invention, the variable composition SiₓGe₁₋ₓ layer can have a first SiₓGe₁₋ₓ sublayer, such as layer 420 of FIG. 4, with a substantially uniform composition and a second SiₓGe₁₋ₓ sublayer, such as layer 520 of FIG. 5, with a continuously variable composition.

Processing conditions used for depositing a Si-containing seed layer, a variable composition SiₓGe₁₋ₓ layer, and a Si cap layer, can include a process chamber pressure less than about 100 Torr. By way of example only, in a batch-type processing system, the chamber pressure can be less than about 1 Torr, for example about 0.3 Torr. By way of further example only, in a single wafer processing system, the chamber pressure can be in the range of about 1-20 Torr. The process conditions can further include a substrate temperature between about 500° C. and about 900° C.

In another embodiment of the invention, the SiGe thin layer semiconductor structure, schematically shown in FIG. 5A, can further contain a Si-containing seed layer 615 formed on the dielectric layer 610, a variable composition SiₓGe₁₋ₓ layer 620 formed on the Si-containing seed layer 615, and a Si cap layer 630 formed on the a variable composition SiₓGe₁₋ₓ layer 620. The Si-containing seed layer 615 can, for example, be an amorphous Si layer or a poly-Si layer formed by a chemical vapor deposition (CVD) process using a Si-containing gas, for example SiH₄, Si₂H₆, SiH₂Cl₂, or Si₂Cl₆. The temperature of substrate 600 when depositing a Si-containing seed layer 615 can be between about 500° C. and about 620° C. An amorphous Si layer can be formed at a substrate temperature below about 540° C., whereas a poly-Si layer can be formed at a substrate temperature above about 600° C. Alternately, the Si-containing seed layer 615 can be a SiₓGe₁₋ₓ layer. The SiₓGe₁₋ₓ seed layer can, for example, have a Ge content of about 0.1, or less. The SiₓGe₁₋ₓ seed layer can, for example, be formed in a chemical vapor deposition process as described above for the variable composition SiₓGe₁₋ₓ layers 440, 520.

In another embodiment of the invention, the Si-containing seed layer 615 can be formed using an atomic layer deposition (ALD) process. In one example, a Si seed layer can be formed by alternately exposing the substrate 600 to a Si-containing gas (e.g., Si₂Cl₆) and H₂. In another example, a SiₓGe₁₋ₓ seed layer can be formed by alternately exposing the substrate 600 to a Si-containing gas (e.g., Si₂Cl₆), H₂, and a Ge-containing gas (e.g., GeH₄). The thickness of the Si-containing seed layer 615 can, for example, between about 25 Å and about 50 Å.

FIG. 6 illustrates a computer system 1201 with which an embodiment of the present invention may be implemented. The computer system 1201 may be used as the controller 124, 90, 240 of FIG. 1A, 1B, or 2, respectively, or a similar controller that may be used with the systems of these figures to perform any or all of the functions described above. The computer system 1201 includes a bus 1202 or other communication mechanism for communicating information, and a processor 1203 coupled with the bus 1202 for processing the information. The computer system 1201 also includes a main memory 1204, such as a random access memory (RAM) or other dynamic storage device (e.g., dynamic RAM (DRAM), static RAM (SRAM), and synchronous DRAM (SDRAM)), coupled to the bus 1202 for storing information and instructions to be executed by processor 1203. In addition, the main memory 1204 may be used for storing temporary variables or other intermediate information during the execution of instructions by the processor 1203. The computer system 1201 further includes a read only memory (ROM) 1205 or other static storage device (e.g., programmable ROM (PROM), erasable PROM (EPROM), and electrically erasable PROM (EEPROM)) coupled to the bus 1202 for storing static information and instructions for the processor 1203.

The computer system 1201 also includes a disk controller 1206 coupled to the bus 1202 to control one or more storage devices for storing information and instructions, such as a magnetic hard disk 1207, and a removable media drive 1208 (e.g., floppy disk drive, read-only compact disc drive, read/write compact disc drive, tape drive, and removable magneto-optical drive). The storage devices may be added to the computer system 1201 using an appropriate device interface (e.g., small computer system interface (SCSI), integrated device electronics (IDE), enhanced-IDE (E-IDE), direct memory access (DMA), or ultra-DMA).

The computer system 1201 may also include special purpose logic devices (e.g., application specific integrated circuits (ASICs)) or configurable logic devices (e.g., simple programmable logic devices (SPLDs), complex programmable logic devices (CPLDs), and field programmable gate arrays (FPGAs), (not shown). The computer system may also include one or more digital signal processors (DSPs) (not shown), such as the TMS320 series of chips from Texas Instruments, the DSP56000, DSP56100, DSP56300, DSP56600, and DSP96000 series of chips from Motorola, the DSP1600 and DSP3200 series from Lucent Technologies or the ADSP2100 and ADSP21000 series from Analog Devices. Other processors especially designed to process analog signals that have been converted to the digital domain may also be used.

The computer system 1201 may also include a display controller 1209 coupled to the bus 1202 to control a display 1210, such as a cathode ray tube (CRT), for displaying information to a computer user. The computer system includes input devices, such as a keyboard 1211 and a pointing device 1212, for interacting with a computer user and providing information to the processor 1203. The pointing device 1212, for example, may be a mouse, a trackball, or a pointing stick for communicating direction information and command selections to the processor 1203 and for controlling cursor movement on the display 1210. In addition, a printer (not shown) may provide printed listings of data stored and/or generated by the computer system 1201.

The computer system 1201 performs a portion or all of the processing steps of the invention in response to the processor 1203 executing one or more sequences of one or more instructions contained in a memory, such as the main memory 1204. Such instructions may be read into the main memory 1204 from another computer readable medium, such as a hard disk 1207 or a removable media drive 1208. One or more processors in a multi-processing arrangement may also be employed to execute the sequences of instructions contained in main memory 1204. In alternative embodiments, hard-wired circuitry may be used in place of or in combination with software instructions. Thus, embodiments are not limited to any specific combination of hardware circuitry and software.

As stated above, the computer system 1201 includes at least one computer readable medium or memory for holding instructions programmed according to the teachings of the invention and for containing data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the computer system 1201, for driving a device or devices for implementing the invention, and for enabling the computer system 1201 to interact with a human user (e.g., print production personnel). Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor 1203 for execution. A computer readable medium may take many forms, including but not limited to, non-volatile media, volatile media, and transmission media. Non-volatile media includes, for example, optical, magnetic disks, and magneto-optical disks, such as the hard disk 1207 or the removable media drive 1208. Volatile media includes dynamic memory, such as the main memory 1204. Transmission media includes coaxial cables, copper wire and fiber optics, including the wires that make up the bus 1202. Transmission media also may also take the form of acoustic or light waves, such as those generated during radio wave and infrared data communications.

Various forms of computer readable media may be involved in carrying out one or more sequences of one or more instructions to processor 1203 for execution. For example, the instructions may initially be carried on a magnetic disk of a remote computer. The remote computer can load the instructions for implementing all or a portion of the present invention remotely into a dynamic memory and send the instructions over a telephone line using a modem. A modem local to the computer system 1201 may receive the data on the telephone line and use an infrared transmitter to convert the data to an infrared signal. An infrared detector coupled to the bus 1202 can receive the data carried in the infrared signal and place the data on the bus 1202. The bus 1202 carries the data to the main memory 1204, from which the processor 1203 retrieves and executes the instructions. The instructions received by the main memory 1204 may optionally be stored on storage device 1207 or 1208 either before or after execution by processor 1203.

The computer system 1201 also includes a communication interface 1213 coupled to the bus 1202. The communication interface 1213 provides a two-way data communication coupling to a network link 1214 that is connected to, for example, a local area network (LAN) 1215, or to another communications network 1216 such as the Internet. For example, the communication interface 1213 may be a network interface card to attach to any packet switched LAN. As another example, the communication interface 1213 may be an asymmetrical digital subscriber line (ADSL) card, an integrated services digital network (ISDN) card or a modem to provide a data communication connection to a corresponding type of communications line. Wireless links may also be implemented. In any such implementation, the communication interface 1213 sends and receives electrical, electromagnetic or optical signals that carry digital data streams representing various types of information.

The network link 1214 typically provides data communication through one or more networks to other data devices. For example, the network link 1214 may provide a connection to another computer through a local network 1215 (e.g., a LAN) or through equipment operated by a service provider, which provides communication services through a communications network 1216. The local network 1214 and the communications network 1216 use, for example, electrical, electromagnetic, or optical signals that carry digital data streams, and the associated physical layer (e.g., CAT 5 cable, coaxial cable, optical fiber, etc). The signals through the various networks and the signals on the network link 1214 and through the communication interface 1213, which carry the digital data to and from the computer system 1201 maybe implemented in baseband signals, or carrier wave based signals. The baseband signals convey the digital data as unmodulated electrical pulses that are descriptive of a stream of digital data bits, where the term “bits” is to be construed broadly to mean symbol, where each symbol conveys at least one or more information bits. The digital data may also be used to modulate a carrier wave, such as with amplitude, phase and/or frequency shift keyed signals that are propagated over a conductive media, or transmitted as electromagnetic waves through a propagation medium. Thus, the digital data may be sent as unmodulated baseband data through a “wired” communication channel and/or sent within a predetermined frequency band, different than baseband, by modulating a carrier wave. The computer system 1201 can transmit and receive data, including program code, through the network(s) 1215 and 1216, the network link 1214, and the communication interface 1213. Moreover, the network link 1214 may provide a connection through a LAN 1215 to a mobile device 1217 such as a personal digital assistant (PDA) laptop computer, or cellular telephone.

The computer system 1201 may be configured to perform the method of the present invention to fabricate a SiGe thin layer semiconductor structure having a variable composition SiₓGe₁₋ₓ layer on a dielectric. In accordance with the present invention, the computer system 1201 may be configured to provide a higher Ge content near the dielectric and a lower or no Ge content near the Si cap layer formed on the SiₓGe₁₋ₓ layer.

Although only certain embodiments of this invention have been described in detail above, those skilled in the art will readily appreciate that many modifications are possible in the exemplary embodiment without materially departing from the novel teachings and advantages of this invention. Accordingly, all such modifications are intended to be included within the scope of this invention.

1. A method of fabricating a SiGe thin layer semiconductor structure, the method comprising:
providing a substrate having a dielectric layer thereon to a process chamber of a processing system;
forming a variable composition SiₓGe₁₋ₓ layer over the dielectric layer; and
forming a Si cap layer on the variable composition SiₓGe₁₋ₓ layer.

2. The method according to claim 1, wherein the substrate comprises one of a semiconductor substrate, a LCD substrate, and a glass substrate.

3. The method according to claim 1, wherein the dielectric layer comprises at least one of an oxide layer, a nitride layer, an oxynitride layer, and a high-k layer.

4. The method according to claim 1, wherein the variable composition SiₓGe₁₋ₓ layer comprises at least one of a graded SiₓGe₁₋ₓ layer with a graded Ge content and a plurality of SiₓGe₁₋ₓ sub-layers each with different Ge content.

5. The method according to claim 4, wherein the graded Ge content in the SiₓGe₁₋ₓ layer is less than about 0.5.

6. The method according to claim 4, wherein the different Ge contents in the SiₓGe₁₋ₓ sublayers are less than about 0.5.

7. The method according to claim 4, wherein the different Ge contents in the SiₓGe₁₋ₓ sub-layers are less than about 0.3.

8. The method according to claim 1, wherein forming the variable composition SiₓGe₁₋ₓ layer includes providing a graded Ge content, with the Ge content being in the range of about 0.2 to about 0.5 adjacent the dielectric layer and decreasing to a value of 0.1 or less adjacent the Si cap layer.

9. The method according to claim 1, wherein the variable composition SiₓGe₁₋ₓ layer comprises a first SiₓGe₁₋ₓ sublayer formed on the dielectric layer, the first SiₓGe₁₋ₓ sublayer having a Ge content between about 0.5 and about 0.3, and a second SiₓGe₁₋ₓ sublayer formed on the first SiₓGe₁₋ₓ sublayer, the second SiₓGe₁₋ₓ sublayer having a Ge content between about 0.15 and about 0.05.

10. The method according to claim 1, wherein the variable composition SiₓGe₁₋ₓ layer comprises a first SiₓGe₁₋ₓ sublayer formed on the dielectric layer, the first SiₓGe₁₋ₓ sublayer having a Ge content of about 0.2, and a second SiₓGe₁₋ₓ sublayer formed on the first SiₓGe₁₋ₓ sublayer, the second SiₓGe₁₋ₓ sublayer having a Ge content of about 0.1.

11. The method according to claim 1, wherein the providing comprises introducing a substrate into one of a process chamber of a single wafer processing system and a process chamber of a batch-type processing system.

12. The method according to claim 1, wherein the forming a variable composition SiₓGe₁₋ₓ layer comprises exposing the substrate to a Si-containing gas and a Ge-containing gas in a chemical vapor deposition process.

13. The method according to claim 11, wherein the Si-containing gas comprises at least one of SiH₄, Si₂H₆, SiH₂Cl₂, and Si₂Cl₆, and the Ge-containing gas comprises at least one of GeH₄ and GeCl₄.

14. The method according to claim 1, wherein the forming a Si cap layer comprises exposing the substrate to at least one of SiH₄, Si₂H₆, SiH₂Cl₂, and Si₂Cl₆ in a chemical vapor deposition process.

15. The method according to claim 1, further comprising:
forming a Si-containing seed layer on the dielectric layer, wherein the variable composition SiₓGe₁₋ₓ layer is formed on the Si-containing seed layer.

16. The method according to claim 15, wherein the Si-containing seed layer comprises one of amorphous Si and poly-Si.

17. The method according to claim 15, wherein the Si-containing seed layer comprises a SiₓGe₁₋ₓ layer.

18. The method according to claim 15, wherein the Si-containing seed layer comprises a SiₓGe₁₋ₓ layer with Ge content of about 0.1, or less.

19. The method according to claim 15, wherein the forming a Si-containing seed layer comprises exposing the substrate to a Si-containing gas containing at least one of SiH₄, Si₂H₆, SiH₂Cl₂, and Si₂Cl₆ in a chemical vapor deposition process.

20. The method according to claim 19, wherein the exposing further comprises exposing the substrate to an inert gas.

21. The method according to claim 19, wherein the exposing further comprises exposing the substrate to H₂.

22. The method according to claim 15, wherein the forming a Si-containing seed layer comprises performing an atomic layer deposition process.

23. The method according to claim 22, wherein the forming a Si-containing seed layer comprises alternately exposing the substrate to a Si-containing gas and H₂.

24. The method according to claim 22, wherein the forming a Si-containing seed layer comprises alternately exposing the substrate to a Si-containing gas, H₂, and a Ge-containing gas.

25. The method according to claim 1, wherein the forming further comprises heating the substrate to between about 500° C. and about 900° C.

26. The method according to claim 1, further comprising providing a process chamber pressure less than about 100 Torr.

27. The method according to claim 1, further comprising providing a process chamber pressure less than about 1 Torr.

28. A computer readable medium containing program instructions for execution on a processor, which when executed by the processor, cause a processing apparatus to perform the steps in the method recited in claim 1.

29. A computer readable medium containing program instructions for execution on a processor, which when executed by the processor, cause a processing apparatus to perform the steps in the method recited in claim 15.

30. A SiGe thin layer semiconductor structure comprising:
a substrate having a dielectric layer thereon;
a variable composition SiₓGe₁₋ₓ layer over the dielectric layer; and
a Si cap layer on the variable composition SiₓGe₁₋ₓ layer.

31. The thin layer semiconductor structure according to claim 30, wherein the substrate comprises one of a semiconductor substrate, a LCD substrate, and a glass substrate.

32. The thin layer semiconductor structure according to claim 30, wherein the dielectric layer comprises at least one of an oxide layer, a nitride layer, an oxynitride layer, and a high-k layer.

33. The thin layer semiconductor structure according to claim 30, wherein the variable composition SiₓGe₁₋ₓ layer comprises at least one of a graded SiₓGe₁₋ₓ layer with a graded Ge content and a plurality of SiₓGe₁₋ₓ sub-layers each with different Ge content.

34. The thin layer semiconductor structure according to claim 33, wherein the graded Ge content in the SiₓGe₁₋ₓ layer is less than about 0.5.

35. The thin layer semiconductor structure according to claim 33, wherein the thickness of the graded SiₓGe₁₋ₓ layer is between about 600 Å and about 1000 Å.

36. The thin layer semiconductor structure according to claim 33, wherein the different Ge contents in the SiₓGe₁₋ₓ sublayers are less than about 0.5.

37. The thin layer semiconductor structure according to claim 33, wherein the different Ge contents in the SiₓGe₁₋ₓ sub-layers are less than about 0.3.

38. The thin layer semiconductor structure according to claim 30, wherein the thickness of each SiₓGe₁₋ₓ sublayer is between about 300 Å and about 500 Å.

39. The thin layer semiconductor structure according to claim 30, wherein the variable composition SiₓGeₓ layer includes a graded Ge content, with the Ge content being in the range of about 0.2 to about 0.5 adjacent the dielectric layer and decreasing to a value of 0.1 or less adjacent the Si cap layer.

40. The thin layer semiconductor structure according to claim 30, wherein the variable composition SiₓGe₁₋ₓ layer comprises a first SiₓGe₁₋ₓ sublayer formed on the dielectric layer, the first SiₓGe₁₋ₓ sublayer having a Ge content between about 0.5 and about 0.3, and a second SiₓGe₁₋ₓ sublayer formed on the first SiₓGe₁₋ₓ sublayer, the second SiₓGe₁₋ₓ sublayer having a Ge content between about 0.15 and about 0.05.

41. The thin layer semiconductor structure according to claim 30, wherein the variable composition SiₓGe₁₋ₓ layer comprises a first SiₓGe₁₋ₓ sublayer formed on the dielectric layer, the first SiₓGe₁₋ₓ sublayer having a Ge content of about 0.2, and a second SiₓGe₁₋ₓ sublayer formed on the first SiₓGe₁₋ₓ sublayer, the second SiₓGe₁₋ₓ sublayer having a Ge content of about 0.1.

42. The thin layer semiconductor structure according to claim 30, wherein the variable composition SiₓGe₁₋ₓ layer is formed by exposing the substrate to a Si-containing gas and a Ge-containing gas in a chemical vapor deposition process.

43. The thin layer semiconductor structure according to claim 42, wherein the Si-containing gas comprises at least one of SiH₄, Si₂H₆, SiH₂Cl₂, and Si₂Cl₆, and the Ge-containing gas comprises at least one of GeH₄ and GeCl₄.

44. The thin layer semiconductor structure according to claim 30, further comprising:
a Si-containing seed layer between the dielectric layer and
the variable composition SiₓGe₁₋ₓ layer.

45. The thin layer semiconductor structure according to claim 44, wherein the Si-containing seed layer comprises one of amorphous Si and poly-Si.

46. The thin layer semiconductor structure according to claim 44, wherein the Si-containing seed layer comprises a SiₓGe₁₋ₓ layer with Ge content of about 0.10, or less.

47. The thin layer semiconductor structure according to claim 44, wherein the thickness of the Si-containing seed layer is between about 25 Å and about 50 Å.

48. A processing tool for fabricating a SiGe thin layer semiconductor structure comprising:
at least one processing system configured to form a variable composition SiₓGe₁₋ₓ layer on a substrate having a dielectric layer thereon and to form a Si cap layer on the variable composition SiₓGe₁₋ₓ layer;
a transfer system configured for transferring the substrate; and
a controller configured to control the processing tool.

49. The processing tool according to claim 48, wherein the at least one processing system is further configured to form a Si-containing seed layer on the dielectric layer.

50. The processing tool according to claim 48, wherein the processing system comprises one of a batch-type processing system and a single wafer processing system.

51. The processing tool according to claim 48, further comprising a process monitoring system.

52. A processing tool for fabricating a SiGe thin layer semiconductor structure, comprising:
means for providing a substrate having a dielectric layer thereon to a process chamber of a processing system;
means for forming a variable composition SiₓGe₁₋ₓ layer over the dielectric layer; and
means for forming a Si cap layer on the variable composition SiₓGe₁₋ₓ layer.

53. The processing tool according to claim 52, further comprising:
means for forming a Si-containing seed layer on the dielectric layer.
